(19) United States
(12) Patent Application Publication
(10) Pub. No.: US 2005/0224112 A1
(43) Pub. Date: Oct. 13, 2005

(54) Coloring matter sensitization type photoelectric conversion device

(76) Inventors: Yuichi Tokita, Kanagawa (JP); Yusuke Suzuki, Kanagawa (JP)

Correspondence Address: WOLF GREENFIELD & SACKS, PC;FEDERAL RESERVE PLAZA, 600 ATLANTIC AVENUE, BOSTON, MA, 02210-2211, US

(21) Appl. No.: 10/519,887

(22) PCT Filed: Jul. 2, 2003
(86) PCT No.: PCT/JP03/08430

§ 371 Date: Dec. 30, 2004

(30) Foreign Application Priority Data
Jul. 2, 2002 (JP) 2002-193154

(51) Int. Cl. H01L 31/00

(52) U.S. Cl. 136/263; 136/256; 250/214 LS

(57) ABSTRACT

The present invention relates to a dye-sensitized type photoelectric conversion device for generating electric power by using solar light. The dye-sensitized type photoelectric conversion device includes a semiconductor layer on which a sensitizing dye having an acidic group-containing porphyrin polymer expressed by a below-described general formula (1) is carried and an electrolyte layer. 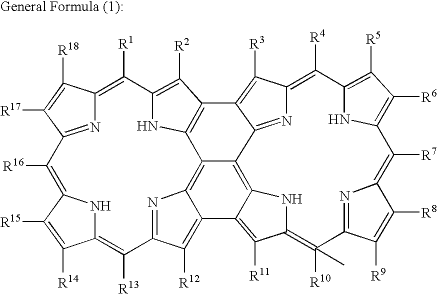
(Here, in the above-described general formula (1), R¹ to R¹⁸ indicate substituents such as hydrogen atoms, halogen atoms and at least one of R¹ to R¹⁸ is an acidic substituent such as 4-carboxyphenyl group.)

### TECHNICAL FIELD

The present invention relates to a dye-sensitized type photoelectric conversion device.

This application claims a priority based on Japanese Patent Application No. 2002-193154 filed in Jul. 2, 2002, in Japan, which is applied to this application by referring thereto.

### BACKGROUND ART

Various kinds of solar cells using a solar light have been conventionally developed as an energy source in place of fossil fuel. As the solar cells that have been conventionally most widely used and most of which have been sold in a market, there are solar cells using silicon. The solar cells using silicon are roughly divided to crystal silicon type solar cells using a monocrystalline silicon or a polycrystalline silicon and amorphous silicon type solar cells.

Particularly, as the solar cells, a large quantity of monocrystalline or polycrystalline silicon has been employed.

In the crystal silicon type solar cells, conversion efficiency showing a performance for converting light (solar) energy to electric energy is higher than that of the amorphous silicon type solar cells. However, since the crystal silicon type solar cells require much energy and time to allow the crystals to grow, the crystal silicon type solar cells have low productivity and have been disadvantageous in view of cost.

Further, the amorphous silicon type solar cells have the conversion efficiency lower than that of the crystal silicon type solar cells. However, the amorphous silicon type solar cells have features that a light absorption property higher than that of the crystal silicon type solar cells, a selecting range of a base is wide, and an area is easily enlarged. The amorphous silicon type solar cells have the productivity higher than that of the crystal silicon type solar cells, however, the amorphous silicon type solar cells need a vacuum process, so that they have still high energy burden.

Since these solar cells use high toxic materials such as gallium, arsenic, silane gas, etc., they have a problem in view of environmental pollution.

On the other hand, as means for solving the above-described problems, solar cells using organic materials have been studied for a long time. However, most of them have a photoelectric conversion efficiency as low as 1%, so that they have not been yet put to practical use.

Among of them, a dye-sensitized type solar cell published in Nature Vol. 353, p 737, 1991 has indicated that this cell can realize a photoelectric conversion efficiency as high as 10% and may be estimated to be produced at low cost. Thus, the dye-sensitized type solar cell has been paid attention to.

In the dye-sensitized type solar cell, a chlorophyll derivative or a zinc complex of porphyrin as well as a ruthenium bipyridine complex, etc. have been proposed as dyes (see Japanese patent Application Laid-Open No. 2002-63949). These dyes have low photoelectric conversion characteristics, so that they can not be satisfactorily put to practical use for the solar cells.

As a reason why the photoelectric conversion characteristics of them are low, a fact that the absorption of the dyes in a visible radiation area is low may be considered. The existing dyes such as a monomer of zinc porphyrin, the chlorophyll derivative, the ruthenium bipyridine complex, etc. have low absorbance in the visible radiation area. In recent years, a stable dye having a high absorption in the visible radiation area has been developed by Osuga et al. (see Science Vol. 293, p 79, 2001, Japanese Patent Application Laid-Open No. 2001-294591 and Japanese Patent Application Laid-Open No. 2002-53578.).

The conventional dye-sensitized type solar cell as described above has a low dye-sensitizing effect in the visible radiation area (400 to 800 nm) that substantially occupies solar light energy and has a problem in view of stability. Therefore, the conventional dye-sensitized type solar cell is hardly put to practical use.

### DISCLOSURE OF THE INVENTION

It is an object of the present invention to provide a new dye-sensitized type photoelectric conversion device that can solve the above-described problems of the conventional dye-sensitized type solar cell.

It is another object of the present invention to provide an inexpensive dye-sensitized type photoelectric conversion device having a high photoelectric conversion efficiency and an excellent durability.

A dye-sensitized type photoelectric conversion device according to the present invention comprises: a semiconductor layer on which a sensitizing dye having an acidic group-containing porphyrin polymer expressed by a below-described general formula (1) as a skeleton of a base is carried and an electrolyte layer between counter electrodes. 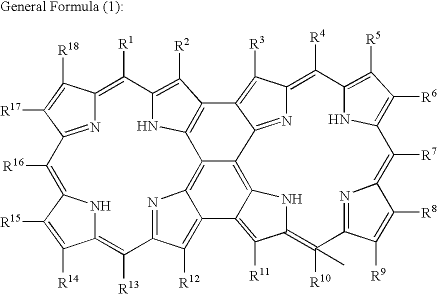
(Here, in the above-described general formula (1), R¹ to R¹⁸ may be the same or different and indicate hydrogen atoms or arbitrary substituents. In this case, at least one of R¹ to R¹⁸ is an acidic substituent.) Another dye-sensitized type photoelectric conversion device according to the present invention comprises: a semiconductor layer on which a sensitizing dye having an acidic group-containing porphyrin polymer expressed by a below-described general formula (2) as a skeleton of a base is carried and an electrolyte layer between counter electrodes. 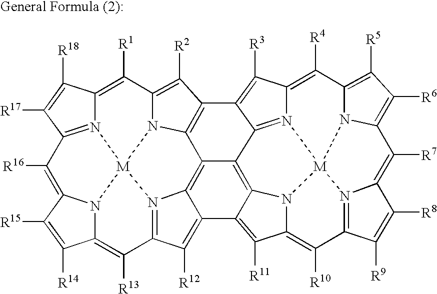
(Here, in the above-described general formula (2), R¹ to R¹⁸ may be the same or different and indicate hydrogen atoms or arbitrary substitutents. In this case, at least one of R¹ to R¹⁸ is an acidic substituent. Further, a group of metals represented by M is arbitrary kinds of metals.)

A still another dye-sensitized type photoelectric conversion device according to the present invention comprises: a semiconductor layer on which a sensitizing dye having an acidic group-containing porphyrin polymer expressed by a below-described general formula (3) as a skeleton of a base is carried and an electrolyte layer between counter electrodes. 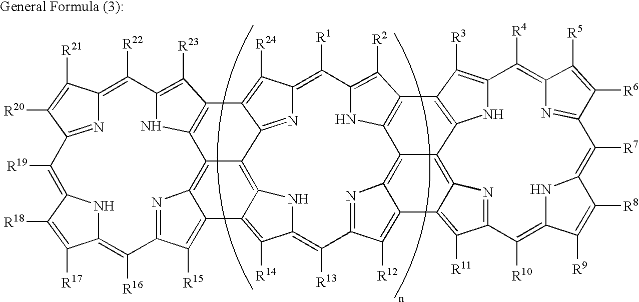
(Here, in the above-described general formula (3), R¹ to R²⁴ may be the same or different and indicate hydrogen atoms or arbitrary substituents. In this case, at least one of R¹ to R²⁴ is an acidic substituent. Further, n is an integer not smaller than 1.)

Further, a still another dye-sensitized type photoelectric conversion device according to the present invention comprises: a semiconductor layer on which a sensitizing dye having an acidic group-containing porphyrin polymer expressed by a below-described general formula (4) as a skeleton of a base is carried and an electrolyte layer between counter electrodes. 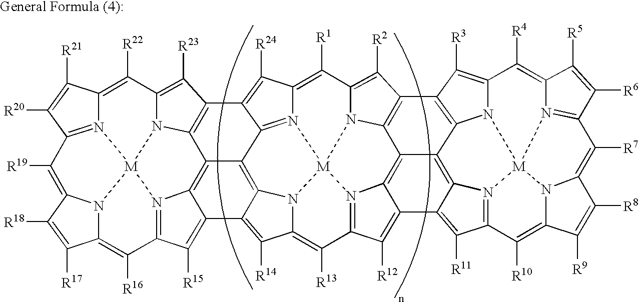
(Here, in the above-described general formula (4), R¹ to R²⁴ may be the same or different and indicate hydrogen atoms or arbitrary substituents. In this case, at least one of R¹ to R²⁴ is an acidic substituent. Further, a group of metals represented by M is arbitrary kinds of metals. n is an integer not smaller than 1.)

In the dye-sensitized type photoelectric conversion device according to the present invention, the semiconductor layer carries the sensitizing dye having the acidic group-containing porphyrin polymer expressed by the general formula (1), (2), (3) or (4) as the skeleton of the base (refer this to as the sensitizing dye composed of the acidic group-containing porphyrin polymer, hereinafter). Accordingly, the semiconductor layer can have a very large light absorption band in a visible radiation area (400 nm to 800 nm) and especially outstandingly improve conversion efficiency when solar light energy is directly converted to electric energy.

Further, the sensitizing dye composed of the acidic group-containing porphyrin polymer expressed by the general formula (1), (2), (3) or (4) is easily synthesized, and an inexpensive and safe material. Thus, this sensitizing dye is advantageously excellent in its productivity.

Further, the sensitizing dye composed of the acidic group-containing porphyrin polymer expressed by the general formula (1), (2), (3) or (4) can form a strong bonding state to the surface of a semiconductor through the acidic group. Thus, the dye-sensitized type photoelectric conversion device is excellent in its durability.

Still other objects of the present invention and specific advantages obtained by the present invention will be more apparent from the explanation of an embodiment with reference to the drawing.

### BRIEF DESCRIPTION OF THE DRAWING

FIG. 1 is a schematic sectional view showing a dye-sensitized type solar cell according to the present invention.

### BEST MODE FOR CARRYING OUT THE INVENTION

Now, a dye-sensitized type photoelectric conversion device according to the present invention will be specifically described. As an acidic substituent used in the dye-sensitized type photoelectric conversion device according to the present invention, a carboxyl group, a sulfonic group, a hydroxyl group, a 4-carboxyphenyl group or the like may be exemplified.

R¹ to R¹⁸ of the above-described general formula (1) or (2), or R¹ to R²⁴ of the above-described general formula (3) or (4) are desirably substituents such as hydrogen atoms, halogen atoms, mercapto groups, amino groups, nitro groups, cyano groups, carboxyl groups, sulfonic groups, hydroxyl groups, substituted or non-substituted alkyl groups, substituted or non-substituted aryl groups, substituted or non-substituted alkoxyl groups, substituted or non-substituted aryloxy groups, substituted or non-substituted alkylthio groups, substituted or non-substituted arylthio groups, substituted or non-substituted alkylamino groups, substituted or non-substituted arylamino groups, substituted or non-substituted carboxylic ester groups, substituted or non-substituted carboxylic amide groups, substituted or non-substituted sulfonic ester groups, substituted or non-substituted sulfonic amide groups, substituted or non-substituted carbonyl groups, substituted or non-substituted silyl groups, substituted or non-substituted siloxy groups, etc. At least one of R¹ to R¹⁸ or at least one of R¹ to R²⁴ is desirably the acidic substituent such as a carboxyl group, a sulfonic group, a hydroxyl group, a 4-carboxyphenyl group or the like.

In the dye-sensitized type photoelectric conversion device according to the present invention, the semiconductor layer is desirably made of oxide semiconductor.

Here, at least one of the substituents represented by R¹ to R¹⁸ in the general formula (1) or (2), or R¹ to R²⁴ in the general formula (3) or (4) is desirably the acidic substituent such as a carboxyl group, a sulfonic group, a hydroxyl group, a 4-carboxyphenyl group or the like. Accordingly, even when the semiconductor layer is made of the oxide semiconductor, the semiconductor layer is excellent in its adsorption capability and advantageous in forming a complex of the oxide semiconductor and a sensitizing dye. Among the exemplified acidic substituents, the substituents including the carboxyl group and the 4-carboxyphenyl group are especially preferable.

In the above-described general formula (3) or (4), n is an integer not smaller than 1. An upper limit is more preferably set to 2. Specially, n is located within the above-described range, so that an absorbed wavelength of a visible radiation part is not shifted to a long wavelength side and the absorption efficiency of a visible radiation area can be maintained.

Further, in the general formula (2) or (4), as the group of metals (central metals) represented by M, one kind or two or more kinds of metals may be exemplified which are selected from a group including Zn, Mg, Ca, Sr, Ba, Sc, Y, La, Ce, Pr, Nd, Sm, Eu, Gd, Tb, Dy, Ho, Er, Tm, Yb, Lu, Ti, Zr, Hf, V, Nb, Ta, Th, U, Cr, Mo, W, Mn, Tc, Re, Fe, Ru, Os, Co, Rh, Ir, Ni, Pd, Pt, Cu, Ag, Au, Cd, Hg, Al, Ga, In, Tl, Si, Ge, Sn, Pb, As, Sb and Bi. That is, the group of metals represented by M may be composed of mutually different two or more kinds as well as all the same kind. As the group of metals represented by M, Zn, Ni, Cu, Pd and Mg are especially more preferable among the above-described metals.

The sensitizing dye used in the present invention has a structure (one dimensional planar porphyrin polymer) in which porphyrin derivatives are bonded together in one dimensional direction as a basic skeleton. The sensitizing dye may have a form easily estimated from the form of the sensitizing dye, for instance, a two dimensional structure in which the same porphyrin derivative is further bonded to the basic skeleton in a two dimensional direction.

Further, the semiconductor layer may be a semiconductor layer that carries the sensitizing dye composed of at least two kinds of acidic group-containing porphyrin polymer expressed by the general formula (1), (2), (3) or (4). Otherwise, the semiconductor layer may be a semiconductor layer that carries the sensitizing dye composed of at least one kind of acidic group-containing porphyrin polymer expressed by the general formula (1), (2), (3) or (4) and other sensitizing dyes such as a ruthenium bipyridine complex, a chlorophyll derivative, a zinc complex of porphyrin or the like.

In the dye-sensitized type photoelectric conversion device according to the present invention, the semiconductor layer and the electrolyte layer are provided between a transparent base having a transparent conductive film and a conductive base serving as a counter electrode of the transparent base, and electric energy can be generated between the transparent conductive film and the conductive base by a photoelectric conversion.

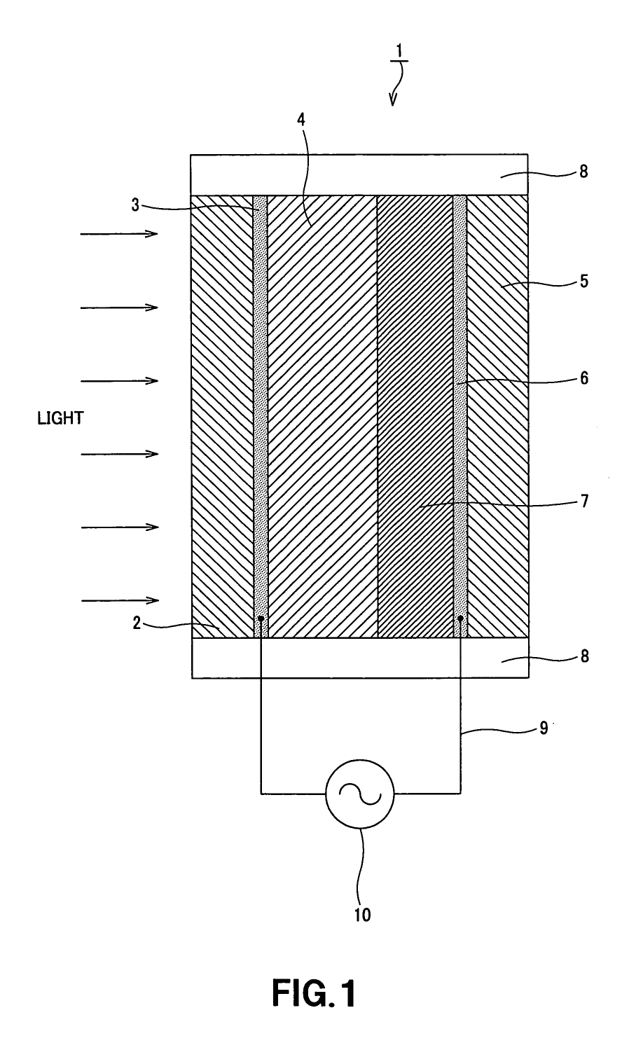

The dye-sensitized type photoelectric conversion device according to the present invention is desirably formed, for example, as a dye-sensitized type solar cell. An example that the present invention is applied to the dye-sensitized type solar cell will be described by referring to FIG. 1.

In the dye-sensitized type solar cell 1 according to the present invention shown in FIG. 1, a semiconductor layer 4 and an electrolyte layer 7 are provided between a transparent base 2 having a transparent conductive film 3 and a base 5 having a conductive film 6 that serves as a counter electrode of the transparent base 2. These members are protected by a case 8. The semiconductor layer 4 is made of, for instance, oxide semiconductor and carries a sensitizing dye composed of an acidic group-containing porphyrin polymer expressed by the general formula (1), (2), (3) or (4). The transparent conductive film 3 is connected to the conductive film 6 by a conductor to form a current circuit 9 having an ammeter 10.

Now, the operating mechanism of the dye-sensitized type solar cell 1 will be described below.

When a solar light L is incident on the transparent base 2 side having the transparent conductive film 3, the sensitizing dye composed of the acidic group-containing porphyrin polymer expressed by the general formula (1), (2), (3) or (4) in the semiconductor layer 4 is excited by light energy to generate electrons. As described above, since the transparent conductive film 3 is connected to the conductive film 6 by the current circuit 9, the electrons are supplied to the transparent conductive film 3 through the semiconductor in the semiconductor layer 4. Thus, electric energy can be taken out between the transparent conductive film 3 and the conductive film 6.

In the dye-sensitized type solar cell 1, since the semiconductor layer 4 carries the sensitizing dye having the acidic group-containing porphyrin polymer expressed by the general formula (1), (2), (3) or (4), the semiconductor layer can have a very large light absorption band in a visible radiation area (400 nm to 800 nm) and outstandingly improve conversion efficiency when solar light energy is directly converted to electric energy.

Further, the sensitizing dye composed of the acidic group-containing porphyrin polymer expressed by the general formula (1), (2), (3) or (4) is easily synthesized, and an inexpensive and safe material. Thus, the sensitizing dye is advantageously excellent in its productivity.

Further, the sensitizing dye composed of the acidic group-containing porphyrin polymer expressed by the general formula (1), (2), (3) or (4) can form a strong bonding state to the surface of the oxide semiconductor through the acidic group. Thus, the dye-sensitized type photoelectric conversion device is excellent in its durability.

As the oxide semiconductor, a well-known semiconductor may be arbitrarily used. Metal oxides such as Ti, Zn, Nb, Zr, Sn, Y, La, Ta, perovskite oxides such as SrTiO₃, CaTiO₃, or the like may be exemplified.

The form of the semiconductor layer (also refer it to as a semiconductor electrode.) made of the oxide semiconductor, or the like is not especially limited to a specific form and various kinds of forms such as a film form, a plate form, a column form, a cylindrical form, etc. may be employed.

As the transparent base having the transparent conductive film, a base in which a thin film of indium oxide, tin oxide, indium tin oxide, etc. is formed on a heat resistance base such as glass base, a plastic base, for instance, polyethylene terephthalate (PET), or a conductive glass base doped with fluorine or the like is used. The thickness of the transparent conductive base is not especially limited to a specific thickness. The thickness is ordinarily set to about 0.3 to 5 mm.

The semiconductor layer made of the oxide semiconductor needs to be formed as a porous layer by sintering semiconductor particles. By referring to a well-known method, for instance (“Recent Advances in Research and Development for Dye-Sensitized Solar Cells” (CMC)), the porous semiconductor layer can be produced in such a way that titanium isopropoxide is dissolved in nitric acid solution to make a hydrothermal reaction and prepare stable titanium oxide colloidal solution, this solution is mixed with polyethylene oxide (PEO) as a binding agent, the mixed material is uniformly blended by a planetary ball mill, and the mixture is screen-printed on, for instance, the conductive glass base doped with fluorine (sheet resistance of 30 Ω/□) and sintered at 450° C.

To allow at least one kind of sensitizing dye of the acidic group-containing porphyrin polymer expressed by the general formula (1), (2), (3) or (4) to be carried on the porous semiconductor layer, for instance, this dye is dissolved in a suitable solvent such as dimethyl formamide. The porous semiconductor layer is immersed and left in the solution until pores of the porous semiconductor layer are sufficiently impregnated with the dye and sufficiently adsorb the dye. Then, the porous semiconductor layer is taken out, cleaned as required and then dried.

As a counter electrode, a material well known as the counter electrode in the conventional solar cell such as aluminum, silver, tin, indium, etc. may be arbitrarily employed. Platinum, rhodium, ruthenium, ruthenium oxide, carbon or the like having a catalytic power for accelerating the reducing reaction of oxidizing redox ions such as I₃-ions are more preferable. These metallic films are preferably formed on the surface of a conductive material by a physical vapor deposition or a chemical vapor deposition.

As an electrolyte provided between both electrodes, materials may be arbitrarily used among electrolytes conventionally employed for the solar cell. As such an electrolyte, there is an electrolyte obtained by dissolving, for instance, iodine and potassium iodide in a mixed solvent of polypropylene carbonate of 25 wt % and ethylene carbonate of 75 wt %.

In the dye-sensitized type photoelectric conversion device such as the solar cell having the above-described structure, when both the electrodes are connected together by the conductor to form the current circuit and the transparent conductive film side is irradiated with false solar light (AM (Air Mass) of 1.5, 100 mW/cm²), the dye-sensitized type photoelectric conversion device can generate power with a high photoelectric conversion efficiency of 13.2% or more. Since this photoelectric conversion efficiency depends on the thickness of the film, the state of the semiconductor layer, the adsorbing state of the dye, the kind of the electrolyte or the like, the photoelectric conversion efficiency can be more improved by selecting the optimum conditions thereof.

Now, specific examples of the present invention will be described below. The present invention is not limited to these examples.

### SYNTHESIS EXAMPLE 1

A measuring flask of 50 ml was used and meso-meso linked Zn(II)-diporphyrin compound (18 mg, 8 mmol) was dissolved in toluene of 30 ml. 2,3-dichloro-5,6-dicyano-1,4-benzoquinone (refer it to as DDQ, hereinafter: 9 mg, 40 mmol) as an oxidizing agent was added to scandium trifluoromethane sulfonate (refer it to as Sc(OTf)₃ hereinafter: 20 mg, 40 mmol). The mixed solution was circulated for one hour. The mixture was diluted with methanol and tetrahydrofuran (THF). The solvent was removed by a rotary evaporator to dissolve a product in the THF and pass an alumina column. After that, the product was recrystallized by benzene/acetonitrile. Thus, a planar porphyrin dimer (12.9 mg, yield of 86%) was obtained which was connected by a total of three bonds including a meso-meso bond that two porphyrin rings are bonded together by carbons at meso positions, and two β-β bonds connected to the meso-meso bond by carbons at β positions adjacent to the meso-meso bond.

When the 1H-NMR spectrum, the UV-Vis spectrum, the MALDI-TOF MAS spectrum of this compound were examined, a planar metallic porphyrin dimer was recognized in which R¹, R⁴, R¹⁰ and R¹³ in the general formula (2) indicated 4-carboxyphenyl groups, the others indicated hydrogen atoms and M indicated Zn. The planar metallic (zinc) porphyrin dimer obtained as described above is referred to as a compound (A), hereinafter.

### SYNTHESIS EXAMPLE 2

The planar zinc porphyrin dimer (compound (A)) obtained as described above was demetalized by concentrated sulfuric acid and trifluoroacetic acid so that a planar metal-free porphyrin dimer could be obtained.

When the 1H-NMR spectrum, the UV-Vis spectrum, the MALDI-TOF MAS spectrum of this compound were examined, a planar porphyrin dimer was recognized in which R¹, R⁴, R¹⁰ and R¹³ in the general formula (1) indicated 4-carboxyphenyl groups and the others indicated hydrogen atoms. The planar porphyrin dimer obtained as described above is referred to as a compound (B), hereinafter.

### SYNTHESIS EXAMPLE 3

A measuring flask of 50 ml was used and meso-meso linked Zn(II)-hexaporphyrin compound (30 mg, 4.7 mmol) was dissolved in toluene of 50 ml. DDQ (27 mg, 120 mmol) as an oxidizing agent was added to Sc(OTf)₃ (60 mg, 120 mmol). The mixed solution was circulated for one hour. The mixture was diluted with methanol and THF. The solvent was removed by a rotary evaporator to dissolve a product in the THF and pass an alumina column. After that, the product was recrystallized by benzene/acetonitrile. Thus, a planar porphyrin hexamer (18.5 mg, yield of 62%) was obtained which was connected by a total of three bonds including a meso-meso bond that six porphyrin rings are bonded together by carbons at meso positions, and two β-β bonds connected to the meso-meso bond by carbons at β positions adjacent to the meso-meso bond.

When the 1H-NMR spectrum, the UV-Vis spectrum, the MALDI-TOF MAS spectrum of this compound were examined, a planar metallic porphyrin hexamer was recognized in which R¹, R⁴, R¹⁰, R¹³, R¹⁶, R²² and R²⁴ in the general formula (4) indicated 4-carboxyphenyl groups, the others indicated hydrogen atoms, M indicated Zn and n was 4. The planar metallic (zinc) porphyrin hexamer obtained as described above is referred to as a compound (C), hereinafter.

### SYNTHESIS EXAMPLE 4

The planar zinc porphyrin hexamer (compound (C)) obtained as described above was demetalized by concentrated sulfuric acid and trifluoroacetic acid so that a planar metal-free porphyrin hexamer could be obtained.

When the 1H-NMR spectrum, the UV-Vis spectrum, the MALDI-TOF MAS spectrum of this compound were examined, a planar porphyrin hexamer was recognized in which R¹, R⁴, R¹⁰, R¹³, R¹⁶, R²² and R²⁴ in the general formula (3) indicated 4-carboxyphenyl groups, the others indicated hydrogen atoms and n was 4. The planar porphyrin hexamer obtained as described above is referred to as a compound (D), hereinafter.

### EXAMPLE 1

TiO₂ paste was produced by referring to “Recent Advances in Research and Development for Dye-Sensitized Solar Cells” (CMC). Titanium isopropoxide of 125 ml was agitated at room temperature and slowly dripped to 0.1 M nitric acid aqueous solution of 750 ml. After a dripping operation was completed, when the solution was moved to a constant temperature bath of 80° C. and agitated for 8 hours, white thick translucent sol solution was obtained. The sol solution was cooled to the room temperature and filtered by a glass filter, and then, the sol solution of 700 ml was measured. The obtained sol solution was moved to an autoclave to perform a hydrothermal reaction process at 220° C. for 12 hours. Then, the sol solution was dispersed by a ultrasonic process for one hour. Then, this solution was concentrated at 40° C. by an evaporator and prepared so that the content of TiO₂ was 11 wt %. To the concentrated sol solution, PEO (polyethylene oxide) having molecular weight of 500000 was added and uniformly mixed by a planetary ball mill to obtain TiO₂ paste having increased viscosity.

The TiO₂ paste obtained as described above was applied with the size of 0.2 cm×0.2 cm on a conductive glass base (sheet resistance of 30 Ω/□) doped with fluorine by a screen printing method and then held at 450° C. for 30 minutes. Then, the TiO₂ was sintered on the conductive glass base to form a porous titanium oxide film.

The above-described porous titanium oxide film was immersed in solutions prepared by respectively dissolving the planar zinc porphyrin dimer (compound (A)) obtained in the above-described synthesis example 1, the planar porphyrin dimer (compound (B)) obtained in the synthesis example 2, the planar zinc porphyrin hexamer (compound (C)) obtained in the synthesis example 3, and the planar porphyrin hexamer (compound (D)) obtained in the synthesis example 4 in dimethyl formamide of 5×10⁻⁴ M. After the porous titanium oxide film was left at 80° C. for 12 hours, the film was cleaned with methanol under an atmosphere of argon and dried.

As a counter electrode, a platinum film having the thickness of 10 μm applied by a sputtering method on a base with ITO (Indium Tin Oxide: transparent conductive oxide having indium oxide doped with tin) was used. As an electrolyte, an electrolyte obtained by dissolving the mixture of iodine of 0.38 g and potassium iodide of 2.49 g in a mixture of 30 g including propylene carbonate of 25 wt % and ethylene carbonate of 75 wt % was used to form a solar cell having the structure as shown in FIG. 1.

As a light source for operating the solar cell formed as described above, false solar light (AM 1.5, 100 mW/cm²) was used. The performances of the solar cells using the compounds (A) to (D) obtained as described above as the sensitizing dyes are respectively measured and the results are shown in a below-illustrated table 1. As comparative examples, solar cells that use compounds including no acidic groups (4-carboxyphenyl groups) in the compounds (A) to (D) and porphyrin compounds as monomers including acidic groups (5, 10, 15, 20-tetrakis-(4-carboxyphenyl) porphyrin) as the sensitizing dyes in the same manner as described above are respectively produced and the performances of these solar cells are also shown in the below-illustrated table 1.

In the table 1, short-circuit current means electric current measured by short-circuiting counter electrodes. Release voltage means voltage generated by opening the counter electrodes. Further, photoelectric conversion efficiency is expressed by a following formula (1).

Formula (1):
Photoelectric conversion efficiency (%)=output electric energy/energy of incident solar light×100

TABLE 1

| | | | Photoelectric |
|---|---|---|---|
| Kind of | Short-circuit | Release | conversion rate |
| sensitizing dye | current (μA) | voltage (V) | (%) |
| (A) of reference | 705 | 0.79 | 11.1 |
| example 1 | | | |
| (B) of reference | 650 | 0.70 | 8.0 |
| example 2 | | | |
| (C) of reference | 620 | 0.65 | 7.6 |
| example 3 | | | |
| (D) of reference | 595 | 0.63 | 7.2 |
| example 4 | | | |
| (A) having no | 12 | 0.50 | 0.08 |
| acidic group | | | |
| (B) having no | 11 | 0.45 | 0.09 |
| acidic group | | | |
| (C) having no | 13 | 0.56 | 0.1 |
| acidic group | | | |
| (D) having no | 15 | 0.48 | 0.08 |
| acidic group | | | |
| 5,10,15,20-tetrakis | 72 | 0.35 | 1.2 |
| (4-carboxyphenyl) | | | |
| porphyrin | | | |

As apparent from the above description, in the dye-sensitized type solar cell according to the present invention, since the semiconductor layer carries the sensitizing dye having the planar acidic group-containing porphyrin polymer expressed by the general formula (1), (2), (3) or (4), the semiconductor layer can have an extremely larger light absorption band in a visible radiation area (400 nm to 800 nm) than a case in which the compound including no acidic group is used or a case in which the monomer is used. The dye-sensitized type solar cell can outstandingly improve conversion efficiency when solar light energy is directly converted to electric energy.

Further, the sensitizing dye composed of the planar acidic group-containing porphyrin polymer expressed by the general formula (1), (2), (3) or (4) is a safely and inexpensively synthesized material, easily available and excellent in its productivity. Further, the sensitizing dye composed of the planar acidic group-containing porphyrin polymer can form a strong bonding state to the surface of the semiconductor. Thus, the dye-sensitized type solar cell is excellent in its durability.

The present invention is described on the basis of the embodiment and the example. However, the above-described example may be modified in various ways on the basis of the technical idea of the present invention.

The above-described example shows an example that the semiconductor layer carries the sensitizing dye composed of the acidic group-containing porphyrin polymer expressed by the general formula (1), (2), (3) or (4). However, the semiconductor layer may be a semiconductor layer that carries a sensitizing dye composed of at least two kinds of acidic group-containing porphyrin polymers expressed by the general formula (1), (2), (3) or (4). Otherwise, the semiconductor layer may be a semiconductor layer that carries the sensitizing dye composed of at least one kind of acidic group-containing porphyrin polymer expressed by the general formula (1), (2), (3) or (4) and other sensitizing dyes such as a ruthenium bipyridine complex, a chlorophyll derivative, a zinc complex of porphyrin or the like.

Further, the acidic group-containing porphyrin polymer expressed by the general formula (1), (2), (3) or (4) may have another form easily thought from the form of the sensitizing dye, for instance, a two-dimensional structure.

Sill further, it is to be understood to a person with ordinary skill in the art that the form, the structure or the employed materials of the dye-sensitized type photoelectric conversion device are not limited to the above-described example and may be suitably selected without departing the attached claims and the gist thereof, and various changes, substitutions or equivalence thereto may be carried out.

### INDUSTRIAL APPLICABILITY

In the dye-sensitized type photoelectric conversion device according to the present invention, since the semiconductor layer carries the sensitizing dye composed of the acidic group-containing porphyrin polymer expressed by the above-described general formula (1), (2), (3) or (4), the semiconductor layer can have a very large light absorption band in a visible radiation area (400 nm to 800 nm). Especially, the dye-sensitized type photoelectric conversion device can outstandingly improve conversion efficiency when solar light energy is directly converted to electric energy.

Further, the sensitizing dye composed of the acidic group-containing porphyrin polymer expressed by the general formula (1), (2), (3) or (4) is an easily synthesized and safe and inexpensive material. Thus, the sensitizing dye is advantageously excellent in its productivity.

Further, the sensitizing dye composed of the acidic group-containing porphyrin polymer expressed by the general formula (1), (2), (3) or (4) can form a strong bonding state to the surface of the semiconductor through the acidic group. Thus, the dye-sensitized type photoelectric conversion device is excellent in its durability.

1. A dye-sensitized type photoelectric conversion device comprising:
a semiconductor layer on which a sensitizing dye having an acidic group-containing porphyrin polymer expressed by a below-described general formula (1) as a skeleton of a base is carried and
an electrolyte layer between counter electrodes. 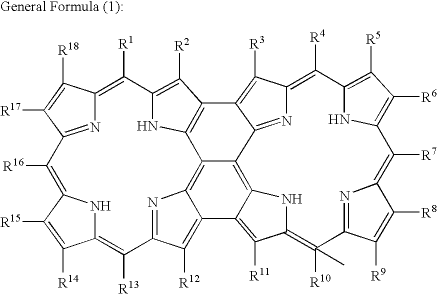
(Here, in the above-described general formula (1), R¹ to R¹⁸ may be the same or different and indicate hydrogen atoms or arbitrary substituents. In this case, at least one of R¹ to R¹⁸ is an acidic substituent.)

2. A dye-sensitized type photoelectric conversion device comprising:
a semiconductor layer on which a sensitizing dye having an acidic group-containing porphyrin polymer expressed by a below-described general formula (2) as a skeleton of a base is carried and
an electrolyte layer between counter electrodes. 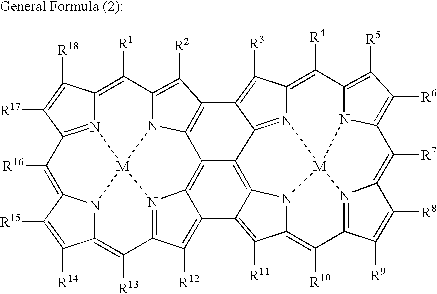
(Here, in the above-described general formula (2), R¹ to R¹⁸ may be the same or different and indicate hydrogen atoms or arbitrary substituents. In this case, at least one of R¹ to R¹⁸ is an acidic substituent. Further, a group of metals represented by M is arbitrary kinds of metals.)

3. A dye-sensitized type photoelectric conversion device comprising:
a semiconductor layer on which a sensitizing dye having an acidic group-containing porphyrin polymer expressed by a below-described general formula (3) as a skeleton of a base is carried and
an electrolyte layer between counter electrodes. 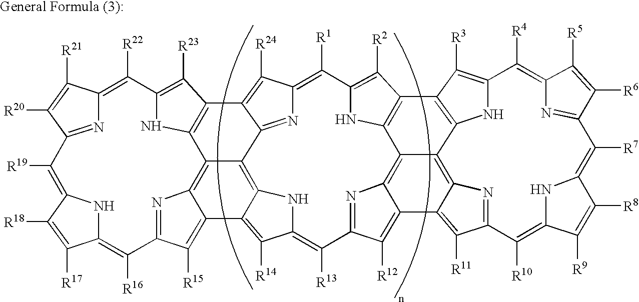
(Here, in the above-described general formula (3), R¹ to R²⁴ may be the same or different and indicate hydrogen atoms or arbitrary substituents. In this case, at least one of R¹ to R²⁴ is an acidic substituent. Further, n is an integer not smaller than 1.)

4. A dye-sensitized type photoelectric conversion device comprising:
a semiconductor layer on which a sensitizing dye having an acidic group-containing porphyrin polymer expressed by a below-described general formula (4) as a skeleton of a base is carried and
an electrolyte layer between counter electrodes. 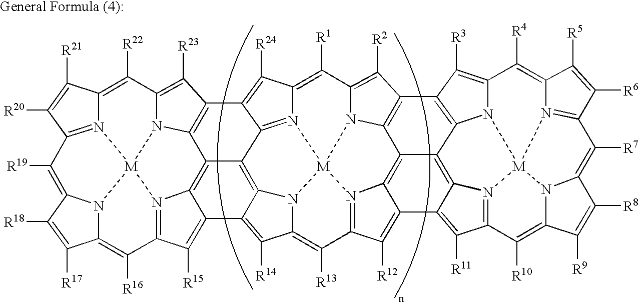
(Here, in the above-described general formula (4), R¹ to R²⁴ may be the same or different and indicate hydrogen atoms or arbitrary substituents. In this case, at least one of R¹ to R²⁴ is an acidic substituent. Further, a group of metals represented by M is arbitrary kinds of metals. n is an integer not smaller than 1.)

5. The dye-sensitized type photoelectric conversion device according to any one of claim 1, 2, 3 or 4, wherein the acidic substituent is a carboxyl group, a sulfonic group, a hydroxyl group, 4-carboxyphenyl group or the like.

6. The dye-sensitized type photoelectric conversion device according to any one of claim 1, 2, 3 or 4, wherein R¹ to R¹⁸ of the general formula (1) or (2) or R¹ to R²⁴ of the general formula (3) or (4) indicate substituents such as hydrogen atoms, halogen atoms, mercapto groups, amino groups, nitro groups, cyano groups, carboxyl groups, sulfonic groups, hydroxyl groups, substituted or non-substituted alkyl groups, substituted or non-substituted aryl groups, substituted or non-substituted alkoxyl groups, substituted or non-substituted aryloxy groups, substituted or non-substituted alkylthio groups, substituted or non-substituted arylthio groups, substituted or non-substituted alkylamino groups, substituted or non-substituted arylamino groups, substituted or non-substituted carboxylic ester groups, substituted or non-substituted carboxylic amide groups, substituted or non-substituted sulfonic ester groups, substituted or non-substituted sulfonic amide groups, substituted or non-substituted carbonyl groups, substituted or non-substituted silyl groups, substituted or non-substituted siloxy groups; and at least one of R¹ to R¹⁸ or at least one of R¹ to R²⁴ is the acidic substituent such as a carboxyl group, a sulfonic group, a hydroxyl group, a 4-carboxyphenyl group or the like.

7. The dye-sensitized type photoelectric conversion device according to claim 1 or 4, wherein the group of metals represented by M in the general formula (2) or (4) includes one kind or two or more kinds of metals selected from a group including Zn, Mg, Ca, Sr, Ba, Sc, Y, La, Ce, Pr, Nd, Sm, Eu, Gd, Tb, Dy, Ho, Er, Tm, Yb, Lu, Ti, Zr, Hf, V, Nb, Ta, Th, U, Cr, Mo, W, Mn, Tc, Re, Fe, Ru, Os, Co, Rh, Ir, Ni, Pd, Pt, Cu, Ag, Au, Cd, Hg, Al, Ga, In, Tl, Si, Ge, Sn, Pb, As, Sb and Bi.

8. The dye-sensitized type photoelectric conversion device according to any one of claims 1 to 4, wherein the semiconductor layer is composed of an oxide semiconductor.

9. The dye-sensitized type photoelectric conversion device according to any one of claims 1 to 4, wherein the semiconductor layer carries a sensitizing dye made of at least two kinds of the acidic group-containing porphyrin polymer expressed by the general formula (1), (2), (3) or (4).

10. The dye-sensitized type photoelectric conversion device according to any one of claims 1 to 4, wherein the semiconductor layer carries a sensitizing dye made of at least one kind of the acidic group-containing porphyrin polymer expressed by the general formula (1), (2), (3) or (4) and other sensitizing dyes such as a ruthenium bipyridine complex, a chlorophyll derivative, a zinc complex of porphyrin or the like.

11. The dye-sensitized type photoelectric conversion device according to any one of claims 1 to 4, wherein the semiconductor layer and the electrolyte layer are provided between a transparent base having a transparent conductive film and a conductive base serving as a counter electrode of the transparent base, and electric energy is generated between the transparent conductive film and the conductive base by a photoelectric conversion.

12. The dye-sensitized type photoelectric conversion device according to claim 11, wherein the dye-sensitized type photoelectric conversion device is a dye-sensitized type solar cell.
